(19) United States
(12) Patent Application Publication
(10) Pub. No.: US 2018/0237941 A1
(43) Pub. Date: Aug. 23, 2018

(54) METHODS FOR FORMING NANOWIRE PHOTONIC DEVICES ON A FLEXIBLE POLYCRYSTALLINE SUBSTRATE

(71) Applicant: Ohio State Innovation Foundation, Columbus, OH (US)

(72) Inventors: Roberto C. Myers, Columbus, OH (US); Brelon J. May, Columbus, OH (US); A.T.M. Golam Sarwar, Hillsboro, OR (US)

(21) Appl. No.: 15/902,245

(22) Filed: Feb. 22, 2018

Related U.S. Application Data
(60) Provisional application No. 62/461,979, filed on Feb. 22, 2017.

(51) Int. Cl. C30B 23/02; H01L 21/02; C30B 25/18; C30B 29/40; C30B 29/60

(52) U.S. Cl. CPC C30B 23/025; H01L 21/02425; H01L 21/0254; H01L 21/02603; H01L 33/007; H01L 21/02631; C30B 25/18; C30B 29/406; C30B 29/605; H01L 21/0262

(57) ABSTRACT

An example method of forming a photonic device is described herein. The method can include providing a flexible polycrystalline substrate, and growing a nanowire heterostructure on the flexible polycrystalline substrate. Optionally, the method can further include fabricating a light emitting diode (LED), a photodiode, a laser, a solar cell, or a photocatalytic water splitter with the nanowire heterostructure.

### CROSS-REFERENCE TO RELATED APPLICATIONS

This application claims the benefit of U.S. provisional patent application No. 62/461,979, filed on Feb. 22, 2017, and entitled “METHODS FOR FORMING NANOWIRE PHOTONIC DEVICES ON A FLEXIBLE POLYCRYSTALLINE SUBSTRATE,” the disclosure of which is expressly incorporated herein by reference in its entirety.

### STATEMENT REGARDING FEDERALLY FUNDED RESEARCH

This invention was made with government support under Grant no. W911NF-13-1-0329 awarded by the Army Research Office and Grant no. DMR-1055164 awarded by the National Science Foundation. The government has certain rights in the invention.

### BACKGROUND

Nanowire based electronics and optoelectronics are attracting more attention due to their successful applications in transistors [1], resonant tunneling diodes [2], light emitting diodes (LEDs) [3], lasers [4], and photodetectors [5]. The formation of dislocations in conventional thin film devices due to lattice mismatch strain restricts the choice of substrate and heterointerface.

III-Nitride nanowires have been shown to be more useful in several fields, such as, red and deep ultraviolet lasers[8], [9], photo-electrochemical water splitting [10], and sensors [11], compared to their planar film counter parts. However, both conventional thin-film and nanowire devices are primarily grown on expensive single crystalline substrates. Recently, there has been interest on the growth of GaN nanowires and related materials on low-cost, scalable metal substrates. The use of metallic substrates is also useful for efficient thermal management, as well as enhanced optical extraction for top emitting devices. Additionally, large scale manufacturing, for example roll to roll processing, often requires a flexible substrate, such as thin metal foils.

### SUMMARY

An example method of forming a photonic device is described herein. The method can include providing a flexible polycrystalline substrate, and growing a nanowire heterostructure on the flexible polycrystalline substrate. Additionally, the method can further include fabricating a light emitting diode (LED), a photodiode, a laser, a solar cell, or a photocatalytic water splitter with the nanowire heterostructure.

Alternatively or additionally, the nanowire heterostructure can include a plurality of layers having different compositions.

Alternatively or additionally, a diameter of the nanowire heterostructure can optionally be less than a grain size of the flexible polycrystalline substrate. Alternatively or additionally, the diameter of the nanowire heterostructure can optionally be greater than or equal to the grain size of the flexible polycrystalline substrate. Optionally, the flexible polycrystalline substrate can be a metal foil such as molybdenum (Mo), titanium (Ti), or tantalum (Ta).

Alternatively or additionally, the nanowire heterostructure can optionally have an epitaxial relationship with the flexible polycrystalline substrate. Optionally, the nanowire heterostructure is tilted with respect to a surface of the flexible polycrystalline substrate. Alternatively or additionally, the nanowire heterostructure can optionally be latticed mismatched with respect to the flexible polycrystalline substrate without dislocation formation.

Alternatively or additionally, the nanowire heterostructure is a single crystalline material. Alternatively or additionally, the nanowire heterostructure is a III-Nitride material. The III-Nitride materials can include, but are not limited to, indium nitride (InN), aluminum nitride (AlN), gallium nitride (GaN), AlₓGa₁₋ₓN, InₓGa₁₋ₓN, InₓAl₁₋ₓN, or InAlGaN, where x=0 to 1.

In some implementations, the nanowire heterostructure can optionally be grown using a molecular beam epitaxy (MBE) process. In other implementations, the nanowire heterostructure can optionally be grown using a metal organic chemical vapor phase deposition (MOCVD) process.

Optionally, the MBE process can include baking the flexible polycrystalline substrate at a baking temperature less than a melting point of the flexible polycrystalline substrate.

Alternatively or additionally, the MBE process can include nucleating the nanowire heterostructure at a nucleation temperature from about 550° C. to about 800° C.

Alternatively or additionally, the MBE process can include growing the nanowire heterostructure at a growth temperature from about 600° C. to about 850° C.

Alternatively or additionally, the MBE process can include growing the nanowire heterostructure at a pressure of 2×10⁻⁵ torr using a plasma with a flux. Optionally, the plasma can be a nitrogen plasma or an ammonia plasma. Alternatively or additionally, the flux can be a gallium flux of 6.2×10⁻⁸, an aluminum flux of 4.1×10⁻⁸, or an indium flux of 8.15×10⁻⁸.

This disclosure contemplates that the method of forming a photonic device can be used in roll-to-roll processing. For example, the method can further include growing a plurality of nanowire heterostructures on the flexible polycrystalline substrate, and fabricating a plurality of light emitting diodes (LEDs), a plurality of photodiodes, a plurality of lasers, a plurality of solar cells, or a plurality of photocatalytic water splitters with the nanowire heterostructures.

Other systems, methods, features and/or advantages will be or may become apparent to one with skill in the art upon examination of the following drawings and detailed description. It is intended that all such additional systems, methods, features and/or advantages be included within this description and be protected by the accompanying claims.

### BRIEF DESCRIPTION OF THE DRAWINGS

The components in the drawings are not necessarily to scale relative to each other. Like reference numerals designate corresponding parts throughout the several views.

FIG. 1 is a flow chart illustrating example operations for forming a photonic device.

FIG. 2 is a flow chart illustrating example operations in an MBE process used to form a photonic device.

FIG. 3A illustrates GaN nanowires on a flexible Ti foil. FIGS. 3B-3G are scanning electron microscope (SEM) images. FIG. 3B shows GaN nanowires on a silicon (Si) single crystal (111) substrate. FIG. 3C shows GaN nanowires on a polycrystalline substrate, e.g., a Ti metal foil. FIGS. 3D-3F show different grains in the Ti metal foil of FIG. 3C. FIGS. 3D, 3E, and 3F show grains highlighted by the boxes in FIG. 3C from the top moving in a clockwise direction. FIG. 3G shows GaN nanowires on a polycrystalline substrate, e.g., a Ta metal foil.

FIGS. 4A and 4B are graphs illustrating photoluminescence measurements at 27.6 K of GaN nanowires on Si single crystal substrate, Ta foil, and Ti foil on linear scale (FIG. 4A) and semi-logarithmic scale (FIG. 4B).

FIG. 5 is a graph illustrating time resolved photoluminescence (PL) measurements at 27.6 K of the 358 nm PL peak for GaN nanowires on Si single crystal substrate, Ta foil, and Ti foil. The instrument response function (IRF) is also plotted.

FIG. 6A illustrates example nanowire LEDs fabricated on a Ta metal foil. FIG. 6B is an SEM image of nanowire LEDs fabricated on a Ta metal foil.

FIG. 7 is a graph illustrating electroluminescence measurements of nanowire LEDs grown directly on flexible Ta foil. The inset shows current-voltage characteristics of an LED grown on Ta metal foil as compared to a similar device on n-Si.

### DETAILED DESCRIPTION

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint. While implementations will be described for forming a photonic device (e.g., an LED, a photodiode, a laser, a solar cell, a photocatalytic water splitter, etc.) using an MBE process, it will become evident to those skilled in the art that the implementations are not limited thereto, but are applicable for use with other semiconductor processing techniques such as MOCVD.

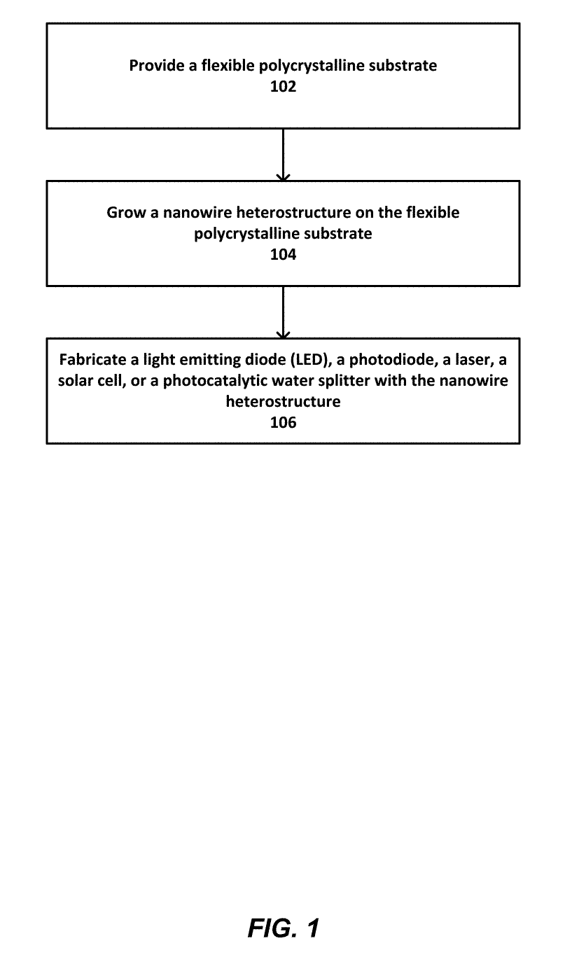

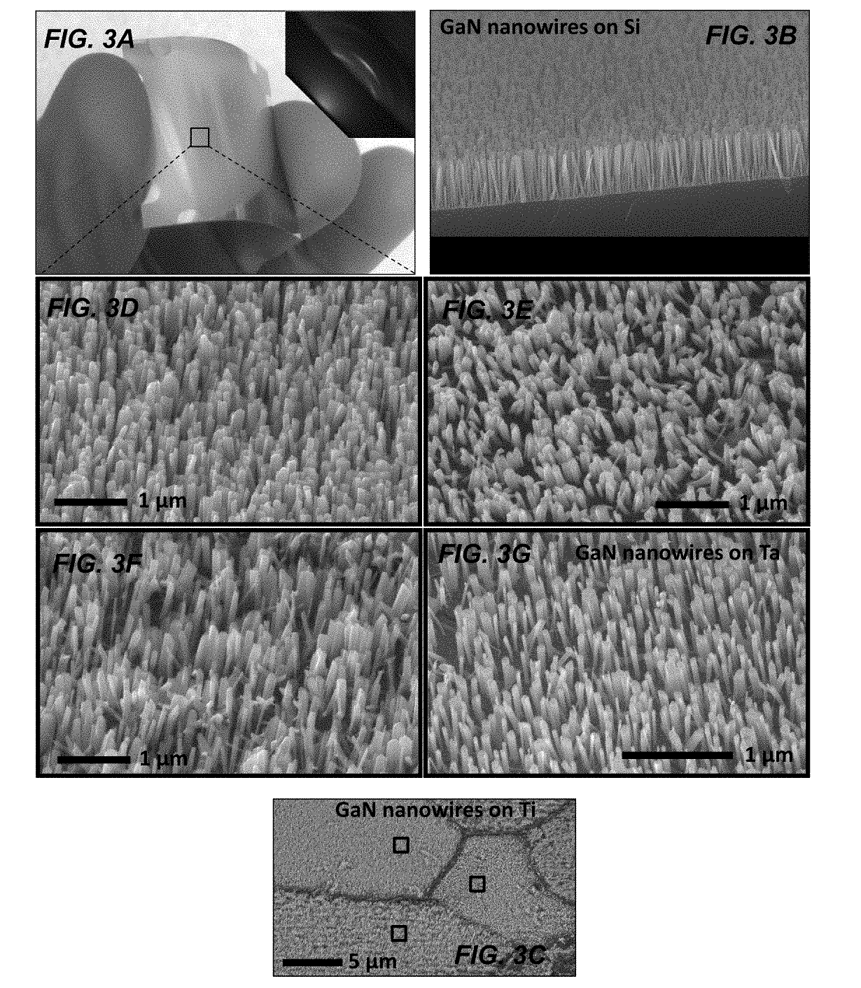

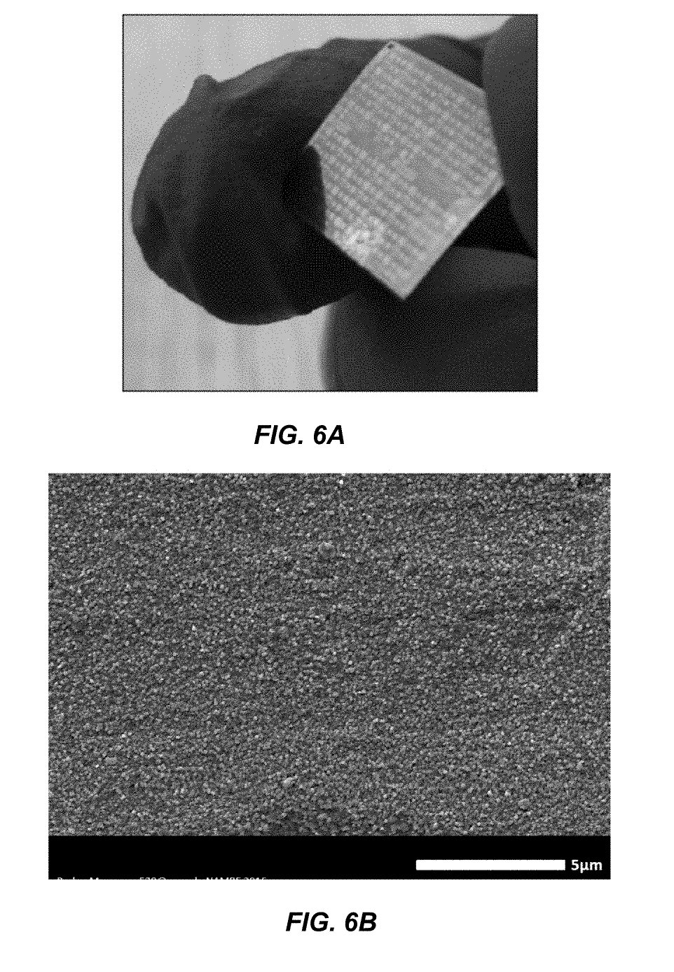

Referring now to FIG. 1, a flow chart illustrating example operations for forming a photonic device is shown. As described herein, a photonic device can include, but is not limited to, a light emitting diode (LED), a photodiode, a laser, a solar cell, or a photocatalytic water splitter. At 102, a flexible polycrystalline substrate can be provided. As used herein, a flexible polycrystalline substrate is a relatively thin substrate such as, for example, a metal foil. A flexible polycrystalline substrate is characterized by its flexibility and/or pliability, i.e., as opposed to rigidity. For example, a polycrystalline substrate is easily bendable. Flexibility can depend on factors including, but not limited to, the type of material, the size of the substrate, and/or the bending radius of the substrate. It should be understood that a flexible polycrystalline substrate is different than a bulk polycrystalline substrate (e.g., bulk metal), which is rigid. Additionally, it should be understood that a flexible polycrystalline substrate is different than a bulk material (e.g., a bulk metal or semiconductor wafer) with a thin film of metal deposited thereon. For example, operational LEDs on metal films were shown by Sarwar et al. [13], demonstrating LEDs emitting in the ultraviolet to green band of AlGaN LEDs grown on Mo films on Si wafers. In Sarwar, however, a thin film of Mo is deposited on a bulk, rigid semiconductor wafer. Additionally, Zhao et al. [14] fabricated red nanowire LEDs on Ti coated bulk (0.5 mm) polycrystalline Mo substrates. In Zhao, however, a thin film of Ti is deposited on a bulk, rigid metal material. In contrast to bulk material with thin films deposited herein, the flexible polycrystalline substrates described herein have nanowire heterostructures grown directly on a surface thereof. Optionally, the flexible polycrystalline substrate can be a metal foil such as molybdenum (Mo), titanium (Ti), or tantalum (Ta). An example flexible polycrystalline substrate (e.g., a Ti metal foil) is shown in FIG. 3A with GaN deposited thereon. This disclosure contemplates that the metal foil can be other metals, including amorphous alloys. At 104, a nanowire heterostructure can be grown on the flexible polycrystalline substrate. An example nanowire heterostructure (e.g., an LED) grown on a flexible polycrystalline substrate (e.g., a Ta foil) is shown in FIGS. 6A and 6B below. The nanowire heterostructure can be a planar device that includes a plurality of layers having different compositions. For example, the nanowire heterostructure can be formed from a single crystalline material. Alternatively or additionally, the nanowire heterostructure can be formed from a III-Nitride material. The III-Nitride materials can include, but is not limited to, indium nitride (InN), aluminum nitride (AlN), gallium nitride (GaN), AlₓGa₁₋ₓN, InₓGa₁₋ₓN, InₓAl₁₋ₓN, or InAlGaN, where x=0 to 1. Additionally, at 106, a light emitting diode (LED), a photodiode, a laser, a solar cell, a photocatalytic water splitter, or other photonic device can be fabricated with the nanowire heterostructure.

As described above, LEDs (e.g., planar, thin film devices) have conventionally been grown on single crystalline substrates such as sapphire, GaN, AlN, etc. The different orientations of underlying grains in polycrystalline foils makes growth of thin film devices extremely difficult due to the resulting thin film devices also being polycrystalline. The defects (e.g., grain boundaries and dislocations) in these thin film devices as a result greatly hamper the quality of the devices. In contrast, the nanowire heterostructures described herein can be grown on a flexible polycrystalline substrate. Another issue is lattice mismatch. Conventional thin film devices are required to have atomic spacings quite similar to the substrate material. Otherwise, the stresses create extended defects reducing the quality of the devices. In contrast, the nanowire heterostructures described herein overcome lattice mismatch problems because nanowires have a large surface area-to-volume ratio. This allows the base of the nanowire to match the flexible polycrystalline substrate, and the resulting strain is relieved at the nanowire sidewalls, which maintains a perfect crystalline quality. In other words, the nanowire heterostructures described herein can optionally be latticed mismatched with respect to the flexible polycrystalline substrate without dislocation formation. The large strain accommodation capability of nanowires due to large surface area-to-volume ratio not only permits large lattice mismatched heterostructures without dislocation formation, but also allows the formation of unconventional heterostructures which are otherwise impossible in conventional planar films.

Another advantage of nanowires is that nanowire diameter can be smaller than the grains in the flexible polycrystalline substrate (e.g., a metal foil). This allows single crystalline nanowires to be formed inside the individual grains without fear of growing polycrystalline material on top. Therefore, in some implementations, a diameter of the nanowire heterostructure can optionally be less than a grain size of the flexible polycrystalline substrate. It should be understood that a nanowire typically has a diameter equal to about 150 nanometer (nm). This disclosure contemplates that a nanowire can have a diameter that is greater or less than 150 nm. It should also be understood that flexible polycrystalline substrates have grains as large as centimeter scale and as small as nanometer scale depending on the material. In other implementations, a diameter of the nanowire heterostructure can optionally be greater than or equal to a grain size of the flexible polycrystalline substrate.

In some implementations, the nanowire heterostructure can optionally have an epitaxial relationship with the flexible polycrystalline substrate. In some implementations, the nanowire heterostructure does not have an epitaxial relationship with the flexible polycrystalline substrate, for example, when the nanowire heterostructure is grown on an amorphous metal substrate. Optionally, the nanowire heterostructure is tilted with respect to a surface of the flexible polycrystalline substrate.

This disclosure contemplates that the method of forming a photonic device can be used in roll-to-roll processing. For example, the method can further include growing a plurality of nanowire heterostructures on the flexible polycrystalline substrate, and fabricating a plurality of light emitting diodes (LEDs), a plurality of photodiodes, a plurality of lasers, a plurality of solar cells, or a plurality of photocatalytic water splitters with the nanowire heterostructures.

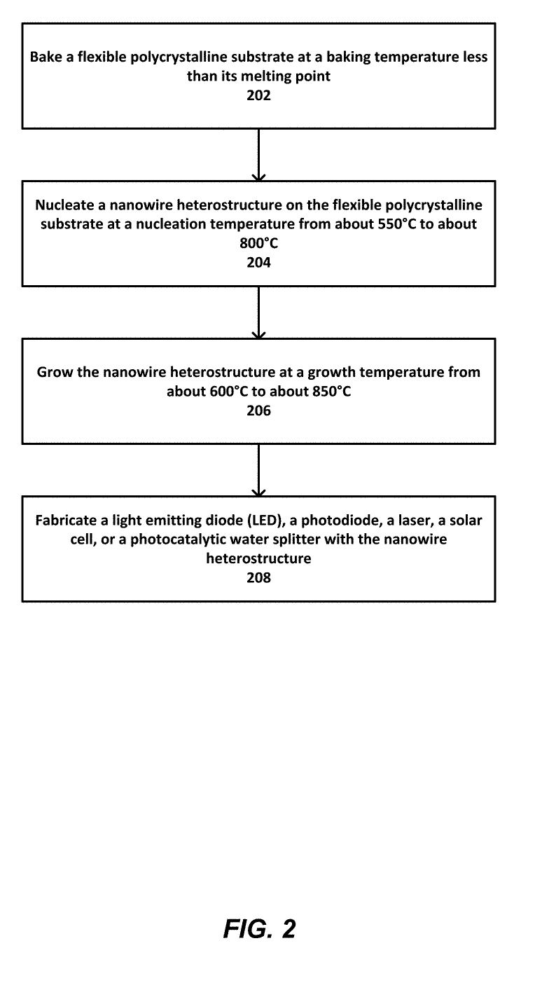

Referring now to FIG. 2, a flow chart illustrating example operations in an MBE process is shown. MBE is a process used for thin-film deposition of crystals, e.g., for manufacturing semiconductor devices. MBE can be performed using any MBE system known in the art. For example, as described below, MBE is performed using a VEECO GEN 930 system from VEECO INSTRUMENTS, INC. of Town of Oyster Bay, N.Y. equipped with a RIBER plasma source from RIBER S. A. of Bezons, France. Before starting the MBE process, the flexible polycrystalline substrate (e.g., metal foil) can be cleaned, for example, using acetone, methanol, isopropyl alcohol, or other cleaning agent known in the art, using an ultrasonic cleaning process. At 202, the flexible polycrystalline substrate can optionally be baked at a baking temperature less than its melting point. It should be understood that baking ensures a clean growth surface and/or prevents contamination of the MBE chamber. In some implementations, the flexible polycrystalline substrate can be baked at about 120° C. under vacuum in the load chamber of the MBE system followed by baking at greater than about 550° C. for greater an 1 hour in a buffer chamber of the MBE system. The flexible polycrystalline substrate can then be brought to a temperature about 20° C. greater than the maximum growth temperature for about 1 minute in a growth chamber of the MBE system. This disclosure contemplates using baking temperatures and times other than those provided in the examples. The baking temperature is limited only by the melting point of the flexible polycrystalline substrate. Additionally, longer baking times anneal the flexible polycrystalline substrate, which results in larger grain sizes.

At 204, the nanowire heterostructure can be nucleated at a nucleation temperature from about 550° C. to about 800° C. Optionally, the nucleation temperature can be from about 650° C. to about 700° C. In some implementations, the nanowire heterostructure can be nucleated for about 5 minutes at 750° C. This disclosure contemplates using nucleation temperatures and times other than those provided in the examples. For example, nucleation can be performed at lower temperatures for shorter times and/or higher temperatures for longer times. At 206, the nanowire heterostructure can be grown at a growth temperature from about 600° C. to about 850° C. In some implementations, when growing an LED, the growth temperature can be about 600° C. for the tunnel junction region, about 800° C. for the quantum well region, and an intermediate temperature (e.g., between about 600° C. and about 850° C.) for the graded semiconductor region (e.g., graded AlGaN regions). As used herein, a graded semiconductor region is a region with non-uniform or inhomogeneous doping. The desired growth temperature of the active region depends on the desired emission wavelength. The growth temperature for the active region is typically desired to be as hot as possible but limited by the melting point of the flexible polycrystalline substrate. For example, for ultraviolet (UV) light emission, AlGaN quantum wells can be grown at a temperature as hot as possible but limited by melting point of the flexible polycrystalline substrate. For visible light emission, InGaN quantum wells can be grown at lower temperatures. Additionally, this disclosure contemplates that nanowire heterostructures can be formed by selecting the appropriate III/V flux ratio, substrate temperature, and/or shutter protocol to realize the desired composition variation.

The MBE process can include growing the nanowire heterostructure at a pressure of about 2×10⁻⁵ torr using a plasma with a flux. Optionally, the plasma can be a nitrogen plasma or an ammonia plasma. This disclosure contemplates using growth pressures other than those provided in the examples. Alternatively or additionally, the flux can be a gallium flux of about 6.2×10⁻⁸, an aluminum flux of about 4.1×10⁻⁸, or an indium flux of about 8.15×10⁻⁸. This disclosure contemplates using fluxes other than those provided in the examples. For example, the fluxes can be roughly doubled or halved (with temperature and/or time adjustments) to achieve the same nanowire heterostructures but with growth at faster or slower rates, respectively.

At 208, an LED, a photodiode, a laser, a solar cell, a photocatalytic water splitter, or other photonic device can be fabricated with the nanowire heterostructure. For example, an LED can be fabricated with the nanowire heterostructure. In a first step, a semi-transparent top contact later can be evaporated on the nanowire heterostructure (e.g., about 10 nm Ti/20 nm gold (Au)). A photoresist can then be spun and the LED device(s) can be patterned using photolithography. Thereafter, the LED device mesa(s) can be formed by etching (e.g., using wet or dry etching techniques known in the art). In a final step, the remaining photoresist can be removed. This disclosure contemplates using semiconductor fabrication processes other than those provided in the examples.

### EXAMPLES

Using molecular beam epitaxy, self-assembled AlGaN nanowires (e.g., nanowire heterostructures as described herein) can be grown directly on Ta and Ti foils (e.g., flexible polycrystalline substrates as described herein). Scanning electron microscopy shows that the nanowires are locally textured with the underlying metallic grains. Photoluminescence spectra of GaN nanowires grown on metal foils are comparable to GaN nanowires grown on single crystal Si wafers. Similarly, photoluminescence lifetimes do not vary significantly between these samples. Operational AlGaN LEDs can be grown directly on flexible Ta foil with an electroluminescence peak emission of ^{˜}350 nm and a turn-on voltage of ^{˜}5 V. These results pave the way for roll-to-roll manufacturing of solid state optoelectronics.

As described below, MBE has been used to demonstrate the growth of AlGaN nanowire LEDs on flexible Ta and Ti foils. The morphologies of nanowires grown on metal foils are similar to nanowires grown on single crystal Si wafers as revealed through scanning electron microscopy (SEM). Cryogenic temperature micro-photoluminescence (μ-PL) measurements show a dominant neutral donor-bound A exciton recombination in nanowires grown on Ta and Ti foils. Time-resolved μ-PL measurements show similar PL decay times for nanowires grown on metal foils compared to nanowires on Si wafers indicating comparable optical quality. Finally, a nanowire LED is grown directly on flexible Ta foil emitting in the ultraviolet band.

The Ta and Ti metal foil substrates are 100-μm thick with purities of 99.9% and 99.6%, respectively, and cut into 1 inch squares. The foils are cleaned with standard solvents before vacuum introduction, but no other surface preparation is performed. They are vacuum baked at 600° C. for one hour before introduction to the growth reactor. Self-assembled catalyst-free GaN nanowires are grown on the foils using plasma-assisted MBE in a VEECO GEN 930 system equipped with a RIBER N₂ plasma source. The Ga beam equivalent pressure is 6.20×10⁻⁸ Torr measured using a beam flux monitoring (BFM) ion gauge. A nitrogen flow rate of 7.5 sccm is used with a plasma power of 500 W, which gives a N-limited growth rate of ^{˜}670 nm/hr. A III-V ratio of 0.18 is used during growth. The substrate is rotated away from the plasma source when striking to avoid nitridation of the surface. The nanowires are grown employing a two-step growth method [15] allowing for separate control over the density and height of the structures. For growth on Si, Ta and Ti, GaN nanowires are first nucleated at 750° C. for 5 minutes then growth proceeds at 800° C. for 2 hours. Reflection high energy electron diffraction (RHEED) for the starting foils is difficult to obtain due to their unpolished, polycrystalline surface. However, once nanowires form, RHEED reveals a spotted ring pattern (see FIG. 3C) that is similar to that of nanowires grown on single crystalline Si. This spotted ring configuration arises as a superposition of patterns from the single crystalline nature of the wires (spots) and the various orientations to the substrate (rings).

An image of GaN nanowires grown on a flexible Ti foil is shown in FIG. 3A. SEM measurements were carried out on a FEI/Philips Sirion for GaN nanowires grown on each substrate. FIG. 3B shows the nanowires grown on a single crystalline Si substrate. The nanowires on Si grow along the c-axis approximately perpendicular to the substrate. SEM images of wires grown on multiple grains of the Ti foil are shown in FIGS. 3C-3F, and an SEM image of the nanowires grown on Ta foil is shown in FIG. 3G. The nanowires on metal foils are uniformly tilted with respect to the surface normal within the individual grains of the foils as shown in FIGS. 3C-3F. The wires have similar heights and radii, and are evenly distributed throughout the region. However, the density and tilt direction vary between different grains which suggest an epitaxial relationship with the metals directly below the nanowire. The Ta foil gives less variation between regions, and the individual regions are larger than those compared to the Ti foil (SEM images not shown).

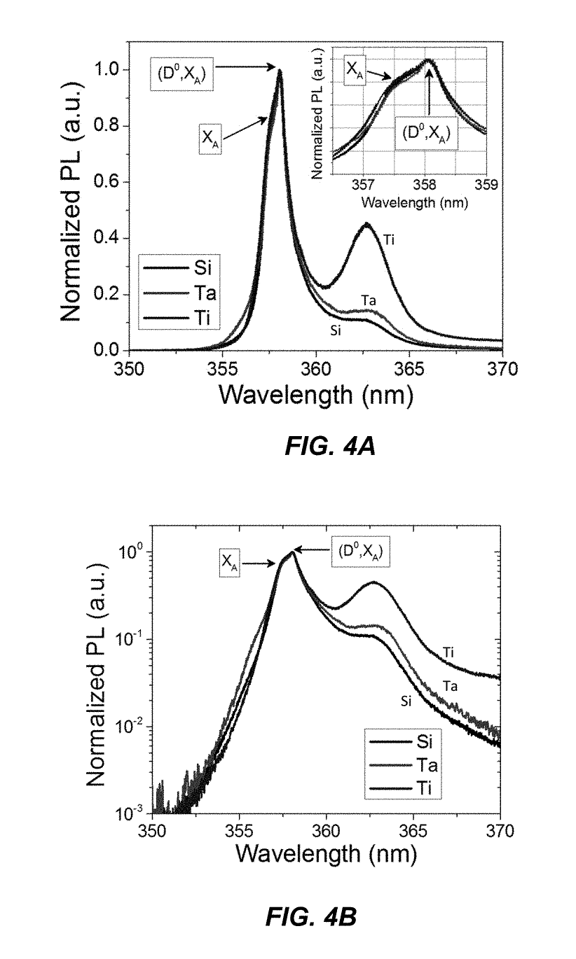

FIGS. 4A and 4B illustrate normalized μ-PL spectra of the as-grown nanowires on Si, Ta, and Ti at 27.6 K on linear scale (FIG. 4A) and semi-logarithmic scale (FIG. 4B). The nanowires were optically excited using a third harmonic (267 nm) of a mode-locked Ti:sapphire oscillator (Coherent Chameleon Ultra II) operating at 800 nm and 80 MHz. The samples were illuminated with an average power of 125 μW and focused on the sample surface through a 0.5 NA 36× reflective objective which results in a beam diameter of ^{˜}10 μm. The emission from the samples was collected through a 300 nm long pass filter and passed to a 0.5 m spectrometer (Princeton Instruments SP2500i) equipped with a UV-VIS CCD (Princeton Instruments PIXIS100) and a 1200 g/mm diffraction grating. All the samples show dominant ^{˜}358 nm (3.472 eV) neutral donor bound A exciton (D⁰, X_{A}) recombination [12], [16][18]. A high energy shoulder is also observed at ^{˜}357.5 nm (^{˜}3.477 eV), attributed to free A exciton (X_{A}) recombination [12], [17]. A relatively broad and weak peak at ^{˜}362.7 nm (^{˜}3.427 eV) is observed. It has been previously attributed to surface related excitons [19], or exciton bound to structural defects such as I₁ stacking faults in GaN nanowires [16], which could originate from sidewall coalescence of the nanowires [17], [20], from defects near the bottom surface of the nanowires [21]. No long wavelength defect peaks (yellow luminescence) are observed in any of the samples.

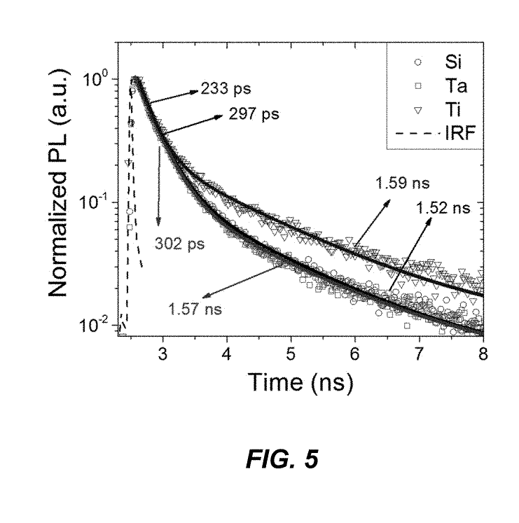

Time-resolved PL was carried out using time-correlated single photon counting spectroscopy using a micro-channel plate (MCP) photomultiplier tube (PMT) detector coupled to a 0.15 m spectrometer. FIG. 5 shows the time-resolved PL at the 358 nm (D⁰, X_{A}) peak (data points) along with the instrument response function (IRF) (dashed line) to show the time resolution of our setup. The PL decay curves are well fitted to a biexponential model (solid lines) with a short lifetime and long lifetime component. For nanowires grown on Ta foil, both the short and long decay components are almost identical to those of nanowires grown on Si. On the other hand, the nanowires on Ti foil show a reduced short decay constant but enhanced long decay constant. Even with this variation, the relatively similar recombination characteristics for all the samples indicates that the nanowires grown on metal foils are of similar optical quality to those grown on single crystalline Si substrates.

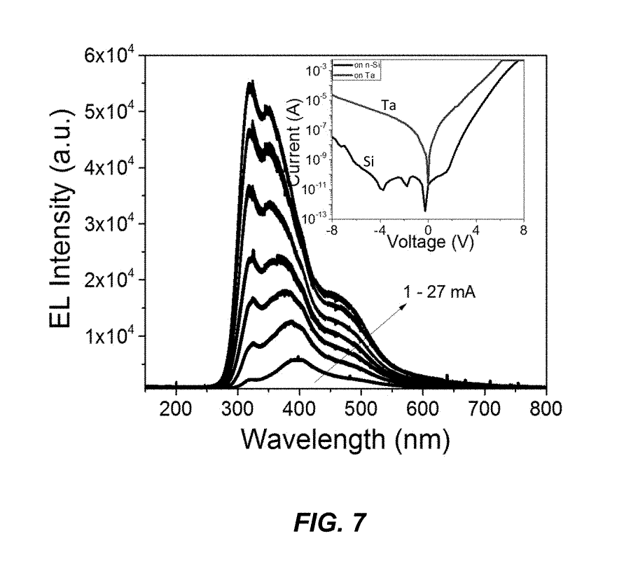

Having established the high quality of GaN nanowires grown on metal foils, an AlGaN LED was also grown on flexible Ta foil. The Ta foil was chosen due to the higher degree of uniformity compared to the Ti foil, as mentioned previously. An example nanowire LED grown on Ta metal foil is shown in FIGS. 6A-6B. Characteristics of the example LED are shown in FIG. 7. The LED heterostructure follows a Ti integrated design that was previously demonstrated on Si [22]. The n-GaN wires were nucleated at 750° C., then a 100 nm n-GaN base was grown at 790° C. followed by a polarization engineered InGaN TJ. A p-type region was formed through composition grading from GaN AlN over 100 nm, taking advantage of the polarization doping. Then an active region consisting of 3×AlGaN quantum wells (QWs) with AlN barriers was grown at 840° C. before growth of the n-type layer achieved through grading back from AlN—GaN. Details of polarization induced doping in nanowires can be found in ref. [23]-[25]. The devices were fabricated using the same process as fabrication of devices on Si. First, an hydrochloric acid (HCl) etch was performed to remove any surface oxide present on the nanowires, followed by deposition of a 10/20 nm Ti/Au top contact. A bottom contact was formed by mechanical removal of the nanowires and a diffused In dot directly on Ta.

Referring now to FIG. 7, the current voltage curve (inset) shows good diode characteristics with a turn on voltage around 5 V, comparable to the same heterostructure grown on n-Si. The electroluminescence spectrum shows ultraviolet emission with a peak at ^{˜}350 nm. The blue shift with increasing current injection in the EL is a result of the screening of the quantum confined Stark effect by the polarization field in the QWs [23]. It is noted that the EL intensity is about 16× lower compared to similar devices on Si. A potential large loss mechanism is observed through the large leakage current, compared to Si devices. This is likely from the inhomogeneous distribution in nanowire tilt and density. Such variations could result in metal deposition on the sidewalls of the nanowires and substrate during fabrication of the top contact. Consequently, a leakage pathway is formed, reducing the number of active nanowires, thus decreasing the overall EL intensity.

In summary, self-assembled GaN NWs were grown by MBE on flexible Ta and Ti foils with optical quality comparable to devices grown on Si. Using this method, nanowire LEDs were directly grown and electrically integrated on flexible Ta foil. In the examples two types of metal foils were tested, but a wider variety of metals may be possible to utilize as long as they are compatible with the growth temperature. The realization of operation nanoLEDs grown directly on flexible metal foils provides a first step towards scalable roll-to-roll manufacturing of nanomaterial based solid-state optoelectronics.

### REFERENCES

[1] X. Miao, K. Chabak, C. Zhang, P. K. Mohseni, D. Walker, and X. Li, “High-Speed Planar GaAs Nanowire Arrays with fmax>75 GHz by Wafer-Scale Bottom-up Growth,” Nano Lett., vol. 15, no. 5, pp. 2780-2786, May 2015.
[2] M. T. Björk, B. J. Ohlsson, C. Thelander, A. I. Persson, K. Deppert, L. R. Wallenberg, and L. Samuelson, “Nanowire resonant tunneling diodes,” Appl. Phys. Lett., vol. 81, no. 23, pp. 4458-4460, December 2002.
[3] F. Qian, S. Gradečak, Y. Li, C.-Y. Wen, and C. M. Lieber, “Core/Multishell Nanowire Heterostructures as Multicolor, High-Efficiency Light-Emitting Diodes,” Nano Lett., vol. 5, no. 11, pp. 2287-2291, 2005.
[4] T. Frost, S. Jahangir, E. Stark, S. Deshpande, A. Hazari, C. Zhao, B. S. Ooi, and P. Bhattacharya, “Monolithic Electrically Injected Nanowire Array Edge-Emitting Laser on (001) Silicon,” Nano Lett., vol. 14, no. 8, pp. 4535-4541, August 2014.
[5] N. Erhard, A. T. M. G. Sarwar, F. Yang, D. W. McComb, R. C. Myers, and A. W. Holleitner, “Optical Control of Internal Electric Fields in Band Gap-Graded InGaN Nanowires,” Nano Lett., vol. 15, no. 1, pp. 332-338, January 2015.
[6] C. V. Falub, H. von Kanel, F. Isa, R. Bergamaschini, A. Marzegalli, D. Chrastina, G. Isella, E. Müller, P. Niedermann, and L. Miglio, “Scaling Hetero-Epitaxy from Layers to Three-Dimensional Crystals,” Science (80-.)., vol. 335, no. 6074, pp. 1330-1334, March 2012.
[7] S. D. Carnevale, C. Marginean, P. J. Phillips, T. F. Kent, A. T. M. G. Sarwar, M. J. Mills, and R. C. Myers, “Coaxial nanowire resonant tunneling diodes from non-polar AlN/GaN on silicon,” Appl. Phys. Lett., vol. 100, no. 14, p. 142115, April 2012.
[8] S. Jahangir, T. Frost, A. Hazari, L. Yan, E. Stark, T. LaMountain, J. M. Millunchick, B. S. Ooi, and P. Bhattacharya, “Small signal modulation characteristics of red-emitting (λ=610 nm) III-nitride nanowire array lasers on (001) silicon,” Appl. Phys. Lett., vol. 106, no. 7, p. 071108, February 2015.
[9] S. Zhao, S. Y. Woo, M. Bugnet, X. Liu, J. Kang, G. A. Botton, and Z. Mi, “Three-Dimensional Quantum Confinement of Charge Carriers in Self-Organized AlGaN Nanowires: A Viable Route to Electrically Injected Deep Ultraviolet Lasers,” Nano Lett., vol. 15, no. 12, pp. 7801-7807, December 2015.
[10] B. AlOtaibi, H. P. T. Nguyen, S. Zhao, M. G. Kibria, S. Fan, and Z. Mi, “Highly Stable Photoelectrochemical Water Splitting and Hydrogen Generation Using a Double-Band InGaN/GaN Core/Shell Nanowire Photoanode,” Nano Lett., vol. 13, no. 9, pp. 4356-4361, September 2013.
[11] J. Wallys, J. Teubert, F. Furtmayr, D. M. Hofmann, and M. Eickhoff, “Bias-Enhanced Optical pH Response of Group III-Nitride Nanowires,” Nano Lett., vol. 12, no. 12, pp. 6180-6186, December 2012.
[12] M. Wölz, C. Hauswald, T. Flissikowski, T. Gotschke, S. Fernández-Garrido, O. Brandt, H. T. Grahn, L. Geelhaar, and H. Riechert, “Epitaxial Growth of GaN Nanowires with High Structural Perfection on a Metallic TiN Film,” Nano Lett., May 2015.
[13] A. T. M. G. Sarwar, S. D. Carnevale, F. Yang, T. F. Kent, J. J. Jamison, D. W. Mccomb, and R. C. Myers, “Semiconductor Nanowire Light-Emitting Diodes Grown on Metal: A Direction Toward Large-Scale Fabrication of Nanowire Devices,” Small, vol. 11, no. 40, pp. 5402-5408, 2015.
[14] C. Zhao, T. K. Ng, N. Wei, A. Prabaswara, M. S. Alias, B. Janjua, C. Shen, and B. S. Ooi, “Facile Formation of High-Quality InGaN/GaN Quantum-Disks-in-Nanowires on Bulk-Metal Substrates for High-Power Light Emitters,” Nano Lett., January 2016.
[15] S. D. Carnevale, J. Yang, P. J. Phillips, M. J. Mills, and R. C. Myers, “Three-Dimensional GaN/AlN Nanowire Heterostructures by Separating Nucleation and Growth Processes,” Nano Lett., vol. 11, no. 2, pp. 866-871, February 2011.
[16] R. Liu, A. Bell, F. A. Ponce, C. Q. Chen, J. W. Yang, and M. A. Khan, “Luminescence from stacking faults in gallium nitride,” Appl. Phys. Lett., vol. 86, no. 2, p. 021908, January 2005.
[17] F. Furtmayr, M. Vielemeyer, M. Stutzmann, A. Laufer, B. K. Meyer, and M. Eickhoff, “Optical properties of Si- and Mg-doped gallium nitride nanowires grown by plasma-assisted molecular beam epitaxy,” J. Appl. Phys., vol. 104, no. 7, p. 074309, October 2008.
[18] F. Schuster, M. Hetzl, S. Weiszer, J. A. Garrido, M. de la Mata, C. Magen, J. Arbiol, and M. Stutzmann, “Position-Controlled Growth of GaN Nanowires and Nanotubes on Diamond by Molecular Beam Epitaxy,” Nano Lett., vol. 15, no. 3, pp. 1773-1779, March 2015.
[19] W. Guo, A. Banerjee, M. Zhang, and P. Bhattacharya, “Barrier height of Pt—In_xGa_{1-x}N (0\leq x\leq 0.5) nanowire Schottky diodes,” Appl. Phys. Lett., vol. 98, no. 18, p. 183116, 2011.
[20] V. Consonni, M. Knelangen, L. Geelhaar, A. Trampert, and H. Riechert, “Nucleation mechanisms of epitaxial GaN nanowires: Origin of their self-induced formation and initial radius,” Phys. Rev. B, vol. 81, no. 8, p. 085310, February 2010.
[21] E. Calleja, M. A. Sanchez-Garcia, F. J. Sánchez, F. Calle, F. B. Naranjo, E. Muñoz, U. Jahn, and K. Ploog, “Luminescence properties and defects in GaN nanocolumns grown by molecular beam epitaxy,” Phys. Rev. B, vol. 62, no. 24, pp. 16826-16834, December 2000.
[22] A. T. M. G. Sarwar, B. J. May, J. I. Deitz, T. J. Grassman, D. W. McComb, and R. C. Myers, “Tunnel junction enhanced nanowire ultraviolet light emitting diodes,” Appl. Phys. Lett., vol. 107, no. 10, p. 101103, September 2015.
[23] S. D. Carnevale, T. F. Kent, P. J. Phillips, M. J. Mills, S. Rajan, and R. C. Myers, “Polarization-induced pn diodes in wide-band-gap nanowires with ultraviolet electroluminescence,” Nano Lett., vol. 12, no. 2, pp. 915-920, February 2012.
[24] S. D. Carnevale, T. F. Kent, P. J. Phillips, A. T. M. G. Sarwar, C. Selcu, R. F. Klie, and R. C. Myers, “Mixed Polarity in Polarization-Induced pn Junction Nanowire Light-Emitting Diodes,” Nano Lett., vol. 13, no. 7, pp. 3029-3035, July 2013.
[25] A. T. M. G. Sarwar, S. D. Carnevale, T. F. Kent, F. Yang, D. W. McComb, and R. C. Myers, “Tuning the polarization-induced free hole density in nanowires graded from GaN to AlN,” Appl. Phys. Lett., vol. 106, no. 3, p. 032102, January 2015.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A method of forming a photonic device, comprising:
providing a flexible polycrystalline substrate; and
growing a nanowire heterostructure on the flexible polycrystalline substrate.

2. The method of claim 1, wherein the nanowire heterostructure comprises a plurality of layers having different compositions.

3. The method of claim 1, wherein a diameter of the nanowire heterostructure is less than a grain size of the flexible polycrystalline substrate.

4. The method of claim 1, wherein a diameter of the nanowire heterostructure is greater than or equal to a grain size of the flexible polycrystalline substrate.

5. The method of claim 1, wherein the nanowire heterostructure has an epitaxial relationship with the flexible polycrystalline substrate.

6. The method of claim 5, wherein the nanowire heterostructure is tilted with respect to a surface of the flexible polycrystalline substrate.

7. The method of claim 1, wherein the nanowire heterostructure is latticed mismatched with respect to the flexible polycrystalline substrate without dislocation formation.

8. The method of claim 1, wherein the nanowire heterostructure comprises a single crystalline material.

9. The method of claim 1, wherein the nanowire heterostructure comprises a III-Nitride material.

10. (canceled)

11. The method of claim 1, wherein the nanowire heterostructure is grown using a metal organic chemical vapor phase deposition (MOCVD) process.

12. The method of claim 1, wherein the nanowire heterostructure is grown using a molecular beam epitaxy (MBE) process.

13. The method of claim 12, wherein growing the nanowire heterostructure on the flexible polycrystalline substrate using the MBE process further comprises baking the flexible polycrystalline substrate at a baking temperature less than a melting point of the flexible polycrystalline substrate.

14. The method of claim 12, wherein growing the nanowire heterostructure on the flexible polycrystalline substrate using the MBE process further comprises nucleating the nanowire heterostructure at a nucleation temperature from about 550° C. to about 800° C.

15. The method of claim 14, wherein growing the nanowire heterostructure on the flexible polycrystalline substrate using the MBE process further comprises growing the nanowire heterostructure at a growth temperature from about 600° C. to about 850° C.

16. The method of claim 12, wherein the nanowire heterostructure is grown at a pressure of about 2×10⁻⁵ torr using a plasma with a flux.

17. The method of claim 16, wherein the plasma is a nitrogen plasma or an ammonia plasma.

18. The method of claim 16, wherein the flux is a gallium flux of about 6.2×10⁻⁸, an aluminum flux of about 4.1×10⁻⁸, or an indium flux of about 8.15×10⁻⁸.

19. The method of claim 1, further comprising fabricating a light emitting diode (LED), a photodiode, a laser, a solar cell, or a photocatalytic water splitter with the nanowire heterostructure.

20. The method of claim 1, further comprising:
growing a plurality of nanowire heterostructures on the flexible polycrystalline substrate; and
fabricating a plurality of light emitting diodes (LEDs), a plurality of photodiodes, a plurality of lasers, a plurality of solar cells, or a plurality of photocatalytic water splitters with the nanowire heterostructures.

21. The method of claim 1, wherein the flexible polycrystalline substrate is a metal foil.

22. (canceled)
